(19) United States
(12) Patent Application Publication
(10) Pub. No.: US 2026/0324228 A1
(43) Pub. Date: Oct. 15, 2026

(54) DISPLAY APPARATUS AND ELECTRONIC DEVICE INCLUDING THE SAME

(71) Applicant: Samsung Display Co., Ltd., Yongin-si (KR)

(72) Inventors: YONGBIN KIM, Yongin-si (KR); HYUNYOUNG CHOI, Yongin-si (KR)

(73) Assignee: Samsung Display Co., Ltd., Yongin-si (KR)

(21) Appl. No.: 19/631,276

(22) Filed: Mar. 27, 2026

(30) Foreign Application Priority Data
Apr. 15, 2025 (KR) 10-2025-0049062

(51) Int. Cl. H10K 59/131; H10K 59/121; H10K 59/123

(52) U.S. Cl. CPC H10K 59/131; H10K 59/1213; H10K 59/123

(57) ABSTRACT

A display apparatus may include a plurality of sub-pixels. Each of the plurality of sub-pixels may include a light-emitting device, and an electronic circuit including a first conductive pattern connected to the light-emitting device, and a first emission control line and a second emission control line that extend in a first direction on one side of the first conductive pattern. A gap between the first emission control line and the first conductive pattern, in a planar view, may be greater than a gap between the second emission control line and the first conductive pattern.

### CROSS-REFERENCE TO RELATED APPLICATION

This application is based on and claims priority under 35 USC §119 to Korean Patent Application No. 10-2025-0049062, filed on Apr. 15, 2025, in the Korean Intellectual Property Office, the disclosure of which is incorporated by reference herein in its entirety.

### BACKGROUND

### 1. Field

One or more embodiments of the present disclosure relate to a display apparatus and an electronic device including the display apparatus.

### 2. Description of Related Art

Electronic devices such as smartphones, tablets, laptop computers, navigation devices for vehicle, smart TVs, etc. are being developed. These electronic devices include a display apparatus for providing information.

In order to satisfy user’s needs for enhanced user experience (UX) and user interface (UI), various types of display apparatuses have been developed. These devices visually display data and may be found in small-sized products, such as mobile phones, or large-sized products such as televisions. A display apparatus includes a plurality of pixels that emit light by receiving electrical signals in order to display images to outside. Each of the pixels includes a display element, for example, an organic light-emitting display apparatus includes organic light-emitting diodes (OLEDs) as display elements. In general, thin film transistors and organic light-emitting diodes are on a substrate and the organic light-emitting diodes emit light by themselves to operate an organic light-emitting display apparatus.

Recently, display apparatuses have been used for various purposes. Accordingly, various designs for improving quality of a display apparatus have been attempted.

### SUMMARY

The present disclosure provides a display apparatus having improved display quality and an electronic device including the same.

In one or more embodiments of the present disclosure, a display apparatus may include a plurality of sub-pixels. Each of the plurality of sub-pixels may include: a light-emitting device; and an electronic circuit including a first conductive pattern connected to the light-emitting device, and a first emission control line and a second emission control line that extend in a first direction on one side of the first conductive pattern. A gap between the first emission control line and the first conductive pattern, in a planar view, is greater than a gap between the second emission control line and the first conductive pattern.

In one or more embodiments of the present disclosure, a display apparatus may include: a plurality of sub-pixels arranged in a first direction and a second direction perpendicular to the first direction, wherein each of the plurality of sub-pixels may include an electronic circuit, the electronic circuit may include a thin film transistor, a light-emitting device connected to the thin film transistor, a first conductive pattern connected to the light-emitting device, and a first emission control line and a second emission control line that extend in the first direction on one side of the first conductive pattern, a reference gate line and a scan line that extend in the first direction on an opposite side of the first conductive pattern, the plurality of sub-pixels may include a first sub-pixel and a second sub-pixel that are immediately next to each other in the second direction from among the plurality of sub-pixels, and the first emission control line of the first sub-pixel and the reference gate line of the second sub-pixel are arranged adjacent to each other in an area between the first conductive pattern of the first sub-pixel and the first conductive pattern of the second sub-pixel.

In one or more embodiments of the present disclosure, an electronic device may include a display apparatus including a display panel generating images, a processor, a memory, and a power supply, wherein the display apparatus may include a plurality of sub-pixels, each of the plurality of sub-pixels may include: an electronic circuit; and a light-emitting device connected to the electronic circuit, the electronic circuit may include a first conductive pattern connected to the light-emitting device, and a first emission control line and a second emission control line that extend in a first direction on one side of the first conductive pattern, and a gap between the first emission control line and the first conductive pattern, in a planar view, is greater than a gap between the second emission control line and the first conductive pattern.

### BRIEF DESCRIPTION OF DRAWINGS

The above and other aspects, features, and advantages of certain embodiments of the disclosure will be more apparent from the following description taken in conjunction with the accompanying drawings in which:

FIG. 1 is a plan view schematically showing an example of a display apparatus according to an embodiment of the present disclosure;

FIG. 2 is a plan view schematically showing the display apparatus of FIG. 1;

FIG. 3 is an equivalent circuit diagram of one pixel in the display apparatus of FIG. 1;

FIG. 4 is a cross-sectional view schematically showing an example of a cross-section taken along line I-I’ of FIG. 1;

FIG. 5 is a plan view schematically showing an example of A in FIG. 2;

FIG. 6 is a graph showing a luminance scattering correlation of a display apparatus according to an embodiment of the present disclosure;

FIG. 7 is a plan view schematically showing another example of A in FIG. 2;

FIG. 8 is a plan view schematically showing another example of A in FIG. 2;

FIG. 9 is a plan view schematically showing another example of A in FIG. 2;

FIG. 10 is a cross-sectional view of an electronic device according to an embodiment of the present disclosure; and

FIG. 11 is schematic diagrams showing electronic devices including the display panel of FIG. 1, according to some embodiments.

### DETAILED DESCRIPTION

Example embodiments are described in greater detail below with reference to the accompanying drawings.

In the following description, like drawing reference numerals are used for like elements, even in different drawings. The matters defined in the description, such as detailed construction and elements, are provided to assist in a comprehensive understanding of the example embodiments. However, it is apparent that the example embodiments can be practiced without those specifically defined matters. Also, well-known functions or constructions are not described in detail since they would obscure the description with unnecessary detail.

In the present disclosure, the term “an embodiment” is intended to encompass one or more embodiments, rather than being limited to a single example. Furthermore, features described in embodiments may be combined and implemented together.

In the present specification, when it is mentioned that a component (or, an area, a layer, a part, etc.) is referred to as being “on”, “connected to” or “combined to” another component, this means that the component may be directly on, connected to, or combined to the other component or a third component therebetween may be present.

Additionally, in the drawings, the thicknesses, proportions, and dimensions of components are exaggerated for effective description. For example, because sizes and/or thicknesses of components in the drawings are arbitrarily illustrated for convenience of explanation, the following embodiments are not limited thereto.

“And/or” includes all of one or more combinations defined by related components.

It will be understood that although the terms “first,” “second,” etc. may be used herein to describe various components, these components should not be limited by these terms. These components are only used to distinguish one component from another. These components are only used to distinguish one component from another. For example, a first component may be referred to as a second component without departing from the scope of the present disclosure, and similarly, the second component may be referred to as the first component.

Singular forms include plural forms unless apparently indicated otherwise contextually.

Also, the terms such as “below”, “lower”, “above”, “upper”, etc. are used to describe the relationships between components shown in the drawings. The above terms are relative concepts and described based on the directions shown in the drawings. For example, it will be understood that when a unit, region, or component is referred to as being “formed on” another layer, region, or component, it can be directly or indirectly formed on the other layer, region, or component. That is, for example, intervening units, regions, or components may be present.

It is to be understood that the terms such as “including,” “having,” and “comprising” are intended to indicate the existence of the features, numbers, steps, actions, components, parts, or combinations thereof disclosed in the specification, and are not intended to preclude the possibility that one or more other features, numbers, steps, actions, components, parts, or combinations thereof may exist or may be added.

Unless otherwise defined, all terms (including technical and scientific terms) used herein have the same meaning as commonly understood by one of ordinary skill in the art to which this subject matter belongs. Additionally, it will be further understood that terms, such as those defined in commonly used dictionaries, should be interpreted as having a meaning that is consistent with their meaning in the context of the relevant art and will not be interpreted in an idealized or overly formal sense unless expressly so defined herein.

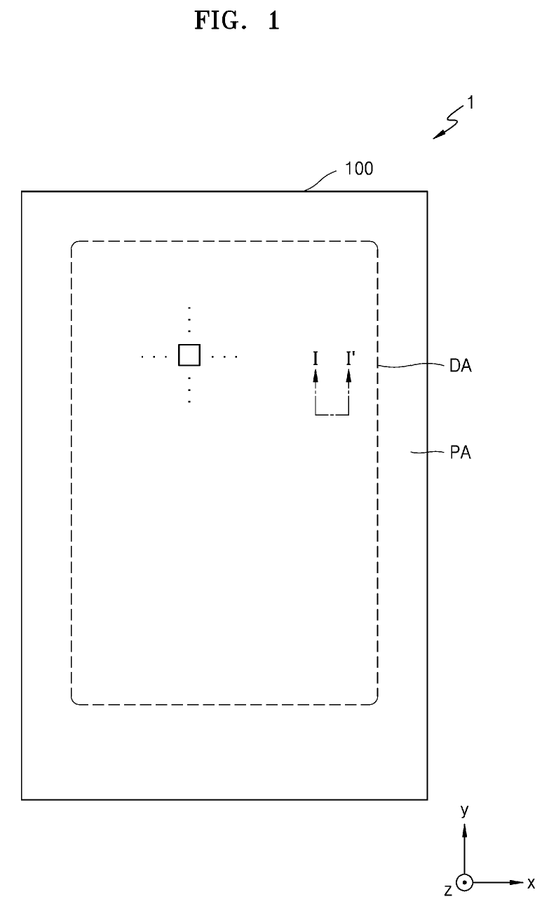

FIG. 1 is a plan view schematically showing an example of a display apparatus according to an embodiment.

Referring to FIG. 1, a display apparatus 1 includes a display area DA for displaying images and a peripheral area PA around the display area DA. The display apparatus 1 may emit light from the display area DA to render images externally. Because the display apparatus 1 includes a substrate 100, it may be understood that the substrate 100 has the display area DA and the peripheral area PA.

The substrate 100 may include various materials such as glass, metal, plastic, etc. In an embodiment, the substrate 100 may include a flexible material. Here, the flexible material is a material that may be bendable, foldable, or rollable. The substrate 100 including the flexible material may include ultra-thin glass, metal, or plastic.

Pixels each including various display elements such as an organic light-emitting diode OLED may be arranged in the display area DA of the substrate 100. The light-emitting diode may be implemented as an organic light-emitting diode including an organic emission layer, or an inorganic light-emitting diode including an inorganic emission layer. The light-emitting diode may have a size of micro-scale or nano-scale. For example, the light-emitting diode may be a micro light-emitting diode or a nanorod light-emitting diode. The nanorod light-emitting diode may include gallium nitride (GaN). In an embodiment, a color conversion layer may be arranged on the nanorod light-emitting diode. The color conversion layer may include quantum dots. The light-emitting diode may be a quantum dot light-emitting diode including a quantum dot emission layer. The pixels P may be arranged in various types such as stripe arrangement, pentile arrangement, mosaic arrangement, etc. to implement images.

FIG. 1 shows that the planar shape of the display area DA has a rectangular shape, but in another embodiment, the display area DA may be provided in a polygonal shape such as triangular, pentagonal, or hexagonal shape, a circular shape, an elliptical shape, an atypical shape, etc.

The peripheral area PA of the substrate 100 is around the display area DA, and may not display images. Various wires for transferring electrical signals that are to be applied to the display area DA, and pads to which a driver IC chip or a printed circuit board is attached may be located in the peripheral area PA.

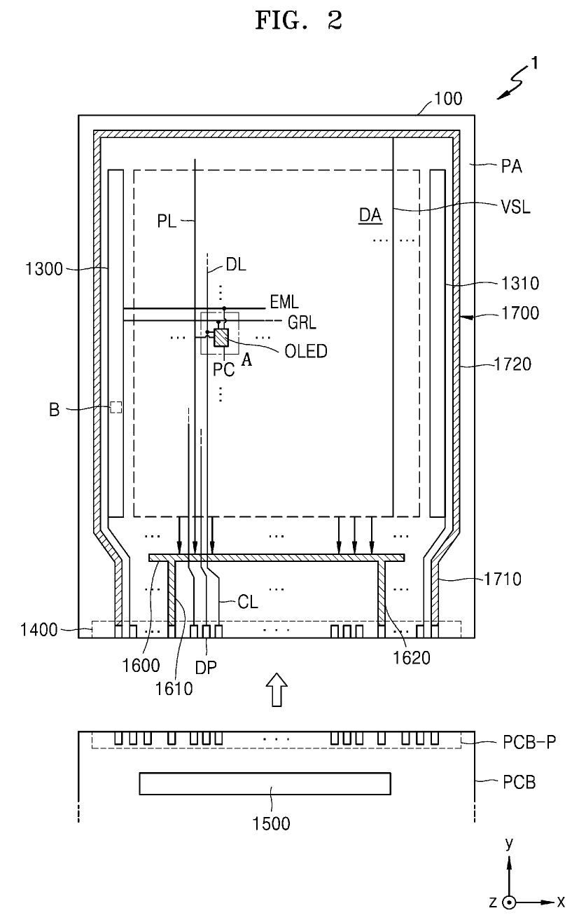

FIG. 2 is a plan view schematically showing the display apparatus of FIG. 1.

Referring to FIG. 2, the display apparatus 1 may include organic light-emitting diodes OLED arranged in the display area DA and pixel circuits PC electrically connected to the organic light-emitting diodes OLED, respectively. The organic light-emitting diodes OLEDs and the pixel circuits PC may be arranged in a first direction (e.g., ±x direction) and a second direction (e.g., ±y direction) in the display area DA. The pixel circuits PC may be electrically connected to emission control lines EML, data lines DL, and driving voltage lines PL arranged in the display area DA.

The emission control lines EML may extend in the first direction (e.g., ±x direction) and may be electrically connected to the pixel circuits PC arranged in the same rows. The data lines DL and the driving voltage lines PL may respectively extend in the second direction (e.g., ±y direction) and may be electrically connected to the pixel circuits PC located in the same columns.

The display apparatus 1 may include a first driving circuit portion 1300, a second driving circuit portion 1310, a first voltage supply line 1600, a second voltage supply line 1700, and a pad portion 1400 arranged in the peripheral area PA.

The first driving circuit portion 1300 and the second driving circuit portion 1310 may each include a gate driving circuit and an emission control driving circuit. The gate driving circuit may provide each pixel circuit PC with a compensation signal, a reference signal, or an initialization signal via a compensation gate line, a reference gate line, or an initialization gate line. The emission control driving circuit may provide each pixel circuit PC with an emission control signal via the emission control line EML.

The second driving circuit portion 1310 may be arranged parallel to the first driving circuit portion 1300 with the display area DA therebetween. Some of the pixel circuits PC arranged in the display area DA may be electrically connected to the first driving circuit portion 1300, and the other may be connected to the second driving circuit portion 1310. In another embodiment, the second driving circuit portion 1310 may be omitted.

The first voltage supply line 1600 and the second voltage supply line 1700 may be arranged in the peripheral area PA. The first voltage supply line 1600 may include a first sub-line 1610 extending toward the end portion of the substrate 100 in the second direction (e.g., y-axis direction) and a second sub-line 1620 extending parallel to a first side surface of the display area DA. The second voltage supply line 1700 has a loop shape having an open side and may partially surround the display area DA. The second voltage supply line 1700 may include a first sub-line 1710 extending toward the end portion of the substrate 100 in the second direction (e.g., y-axis direction) and a second sub-line 1720 extending along a second side, a third side, and a fourth side of the display area DA.

The pad portion 1400 may be arranged in one side of the peripheral area PA. The pad portion 1400 may include a plurality of pads such as data pads DP. The pad portion 1400 may not be covered by an insulating layer but is exposed, and may be electrically connected to a printed circuit board PCB. The pads of the pad portion 1400 may be electrically connected to a terminal portion PCB-P of the printed circuit board PCB. The printed circuit board PCB may transfer a signal or voltage from a controller to the display panel.

Control signals generated by the controller may be respectively transferred to the first driving circuit portion 1300 and the second driving circuit portion 1310 via the printed circuit board PCB and the pad portion 1400.

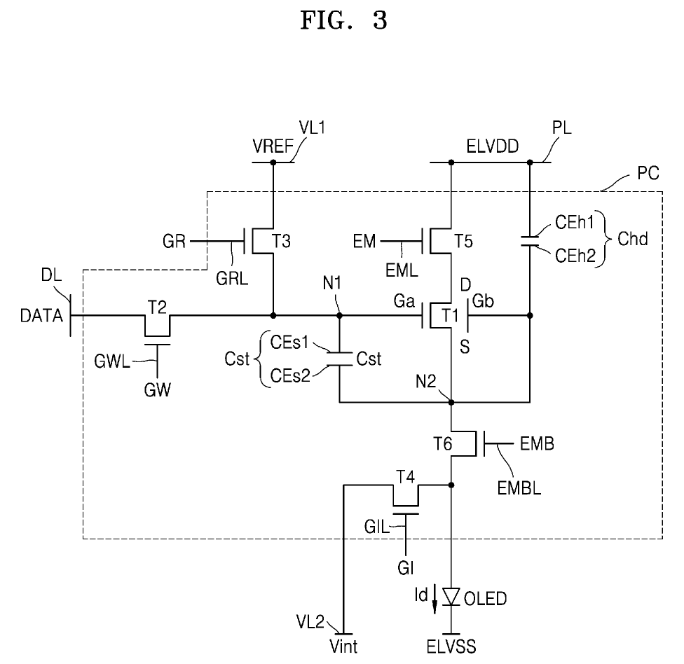

A driving voltage ELVDD (see FIG. 3) generated by the controller may be transferred to the first voltage supply line 1600 via the first sub-line 1610 connected to the pads of the pad portion 1400. The driving voltage ELVDD may be provided to each pixel circuit PC via a driving voltage line PL connected to the first voltage supply line 1600.

A common voltage ELVSS (see FIG. 3) generated by the controller may be transferred to the second voltage supply line 1700 via the first sub-line 1710 connected to the pad of the pad portion 1400. The common voltage ELVSS may be provided to an opposite electrode (or cathode) of the organic light-emitting diode OLED connected to the second voltage supply line 1700. In the display area DA, common voltage lines VSL electrically connected to the second voltage supply line 1700 may be arranged. The common voltage lines VSL may prevent voltage dropping of the second driving voltage, which may occur according to the increase of the display area DA.

The data driving circuit 1500 may be electrically connected to the data lines DL. The data signal (or data voltage) of the data driving circuit 1500 may be provided to each pixel circuit PC via a connection line CL connected to the data pad DP of the pad portion 1400, and the data line DL connected to the connection line CL.

FIG. 2 shows that the data driving circuit 1500 is arranged on the printed circuit board PCB, but in another embodiment, the data driving circuit 1500 may be arranged on the substrate 100. For example, the data driving circuit 1500 may be arranged between the pad portion 1400 and the first voltage supply line 1600.

FIG. 3 is an equivalent circuit diagram of one pixel in the display apparatus of FIG. 1.

Referring to FIG. 3, the pixel P (see FIG. 2) may include the pixel circuit PC connected to the organic light-emitting diode OLED as a display element. The pixel circuit PC may include first to sixth transistors T1, T2, T3, T4, T5, and T6, and capacitors Cst and Chd. The first transistor T1 may be a driving transistor outputting a driving current corresponding to the data signal, and the second to sixth transistors T2, T3, T4, T5, and T6 may be switching transistors transferring signals. A first terminal (first electrode) in each of the first to sixth transistors T1, T2, T3, T4, T5, and T6 may be a source or drain, and a second terminal (second electrode) may be a terminal different from the first terminal. For example, when the first terminal is a drain, the second terminal may be a source.

The pixel circuit PC may be connected to a scan line GWL transferring a scan signal GW, an initialization gate line GIL transferring an initialization signal GI, the reference gate line GRL transferring a reference signal GR, the first emission control line EML transferring a first emission control signal EM, a second emission control line EMBL transferring a second emission control signal EMB, and the data line DL transferring a data signal DATA. Also, the pixel circuit PC may be connected to a driving voltage line PL transferring the driving voltage ELVDD, a first voltage line VL1 transferring a reference voltage VREF, and a second voltage line VL2 transferring an initialization voltage Vint.

The first transistor T1 may be connected between the driving voltage line PL and a second node N2. The first transistor T1 may include a gate, a first terminal, and a second terminal connected to the second node N2. The second terminal may be a source. The gate of the first transistor T1 may include a first gate electrode Ga connected to a first node N1 and a second gate electrode Gb connected to the second node N2. The first gate electrode Ga and the second gate electrode Gb may be arranged to face each other at different layers. The first terminal of the first transistor T1 may be connected to the driving voltage line PL via the fifth transistor T5, and the second terminal may be connected to the pixel electrode of the organic light-emitting diode OLED. The first transistor T1 may receive the transfer of the data signal DATA according to a switching operation of the second transistor T2 and control a current amount of a driving current Id flowing to the organic light-emitting diode OLED.

The second transistor T2 may be connected between the data line DL and the first node N1. The second transistor T2 may include a gate connected to the scan line GWL, a first terminal connected to the data line DL, and a second terminal connected to the first node N1. The second transistor T2 is turned on by the scan signal GW transferred through the scan line GWL to electrically connect the data line DL to the first node N1 and transfer the data signal DATA transferred through the data line DL to the first node N1.

The third transistor T3 may be connected between the first node N1 and the first voltage line VL1. The third transistor T3 may include a gate connected to the reference gate line GRL, a first terminal connected to the first node N1, and a second terminal connected to the first voltage line VL1. The third transistor T3 is turned on by the reference signal GR transferred through the reference gate line GRL, and then, may transfer the reference voltage VREF transferred through the first voltage line VL1 to the first node N1.

The fourth transistor T4 may be connected between the first transistor T1 and the second voltage line VL2. The fourth transistor T4 may include a gate connected to the initialization gate line GIL, a first terminal connected to the second terminal of the sixth transistor T6 and the organic light-emitting diode OLED, and a second terminal connected to the second voltage line VL2. The fourth transistor T4 is turned on by the initialization signal GI transferred through the initialization gate line GIL, and then may transfer the initialization voltage Vint transferred through the second voltage line VL2 to the pixel electrode of the organic light-emitting diode OLED.

The fifth transistor T5 may be connected between the driving voltage line PL and the first transistor T1. The fifth transistor T5 may include a gate connected to the first emission control line EML, a first terminal connected to the driving voltage line PL, and a second terminal connected to the first terminal of the first transistor T1. The fifth transistor T5 may be turned on or turned off according to the first emission control signal EM transferred through the first emission control line EML.

The sixth transistor T6 may be connected between the first transistor T1 and the organic light-emitting diode OLED. The sixth transistor T6 may include a gate connected to the second emission control line EMBL, a first terminal connected to the second node N2, and a second terminal connected to the organic light-emitting diode OLED. The sixth transistor T6 is turned on by the second emission control signal EMB transferred through the second emission control line EMBL, and then may connect the second node N2 to the pixel electrode of the organic light-emitting diode OLED.

FIG. 3 shows that the fifth transistor T5 and the sixth transistor T6 operate respective in response to different emission control signals EM and EMB, but in another embodiment, the fifth transistor T5 and the sixth transistor T6 may operate in response to the same emission control signal.

In an embodiment, the reference signal GR may be substantially synchronized with the scan signal GW of the pixel circuit PC located in a previous row. The initialization signal GI may be substantially synchronized with the scan signal GW. In another embodiment, the initialization signal GI may be substantially synchronized with the scan signal GW or the reference signal GR of the pixel circuit PC located in a next row.

The storage capacitor Cst may be connected between the first node N1 and the second node N2. In other words, the pixel circuit PC included in the display apparatus according to an embodiment of the present disclosure may be a source follower type circuit of which the storage capacitor Cst is connected between the first node N1 and the second node N2. A first storage electrode CEs1 of the storage capacitor Cst may be connected to the first node N1 and a second storage electrode CEs2 may be connected to the second node N2. The storage capacitor Cst may store a threshold voltage of the first transistor T1 and a voltage corresponding to the data signal DATA.

A hold capacitor Chd may be connected between the driving voltage line PL and the second node N2. A first hold electrode CEh1 of the hold capacitor Chd may be connected to the driving voltage line PL and a second hold electrode CEh2 of the hold capacitor Chd may be connected to the second node N2.

The organic light-emitting diode OLED may include a pixel electrode connected to the second node N2 and an opposite electrode facing the pixel electrode, and the opposite electrode may receive the common voltage ELVSS. The opposite electrode may be a common electrode that is common for a plurality of pixels.

FIG. 3 shows the pixel circuit PC includes six transistors and two capacitors, but in another embodiment, the pixel circuit PC may include five transistors and two capacitors. In another embodiment, the pixel circuit PC may include seven transistors and two capacitors.

In a semiconductor layout according to one or more embodiments of the present disclosure, the first emission control line EML, the second emission control line EMBL, and a driving transistor (e.g., the first transistor T1) are arranged such that the distance between the first emission control line EML and a source electrode of the driving transistor (in a planar view) is greater than the distance between the second emission control line EMBL and the source electrode of the driving transistor. This configuration may help reduce overlap capacitance and improves the display quality of the display device.

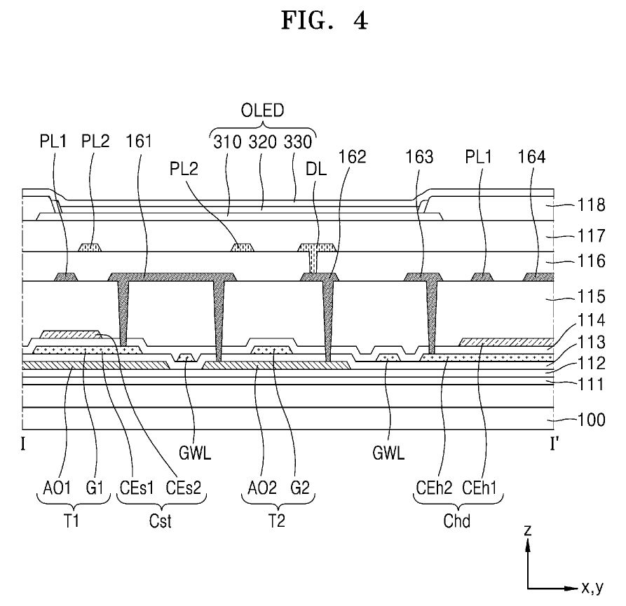

FIG. 4 is a cross-sectional view schematically showing an example of a cross-section taken along line I-I’ of FIG. 1.

Referring to FIG. 4, the first substrate 100 may include a glass material, a ceramic material, a metal material, or a flexible or bendable material. When the substrate 100 is flexible or bendable, the substrate 100 may include a polymer resin such as a polyethersulfone (PES), polyacrylate, polyetherimide (PEI), polyethylene naphthalate (PEN), polyethylene terephthalate (PET), polyphenylene sulfide (PPS), polyarylate, polyimide (PI), polycarbonate (PC), cellulose acetate propionate (CAP), etc.

The substrate 100 may have a single-layered or a multi-layered structure of the above materials, and the multi-layered structure may further include an inorganic layer.

A plurality of sub-pixels may be arranged on the substrate 100, and each of the plurality of sub-pixels may include a circuit unit (also referred to as “electronic circuit”) on the substrate.

The circuit unit may include a buffer layer 111, an insulating layer 112, a first semiconductor layer A01, a second semiconductor layer A02, a first gate insulating layer 113, a second gate insulating layer 114, a first interlayer insulating layer 115, a first planarization layer 116, and a planarization layer 117.

The buffer layer 111 may be located on the substrate 100. The buffer layer 111 may improve flatness of an upper surface of the substrate 100 and may include an oxide layer such as silicon oxide (SiOₓ) and/or a nitride layer such as silicon nitride (SiNₓ), or silicon oxynitride (SiON).

The insulating layer 112 may be arranged to cover a first peripheral semiconductor layer and a buffer semiconductor layer. The insulating layer 112 may include an inorganic material including an oxide or a nitride. For example, the insulating layer 112 may include at least one selected from an insulating material such as silicon oxide (SiO₂), silicon nitride (SiNx), silicon oxynitride (SiON), aluminum oxide (Al₂O₃), titanium oxide (TiO₂), tantalum oxide (Ta₂O₅), hafnium oxide (HfO₂), and zinc oxide (ZnO₂), etc.

The first semiconductor layer A01 of the first transistor T1 and the second semiconductor layer A02 of the second transistor T2 may be arranged on the insulating layer 112. The first semiconductor layer A01 and the second semiconductor layer A02 may include oxide semiconductor.

The first gate insulating layer 113 may be located on the first semiconductor layer A01 and the second semiconductor layer A02. The first gate insulating layer 113 may include an inorganic material including an oxide material or a nitride material. For example, the first gate insulating layer 113 may include at least one selected from an insulating material such as silicon oxide (SiO₂), silicon nitride (SiNx), silicon oxynitride (SiON), aluminum oxide (Al₂O₃), titanium oxide (TiO₂), tantalum oxide (Ta₂O₅), hafnium oxide (HfO₂), zinc oxide (ZnO₂), etc.

A first gate electrode G1, a second gate electrode G2, the scan line GWL, and the second hold electrode CEh2 may be arranged on the first gate insulating layer 113. The first gate electrode G1 may be integrally formed with the first storage electrode CEs1. That is, the first gate electrode G1 may act as the first storage electrode CEs of the storage capacitor Cst, as well as a control electrode of the first transistor T1.

The first gate electrode G1, the second gate electrode G2, the scan line GWL, and the second hold electrode CEh2 are provided on the same layer, and may include the same material. For example, the first gate electrode G1, the second gate electrode G2, the scan line GWL, and the second hold electrode CEh2 may each include aluminum (Al), platinum (Pt), palladium (Pd), argentum (Ag), magnesium (Mg), aurum (Au), nickel (Ni), neodymium (Nd), iridium (Ir), chromium (Cr), lithium (Li), calcium (Ca), molybdenum (Mo), titanium (Ti), tungsten (W), copper (Cu), etc., and may have a single-layered or multi-layered structure including at least one selected from the above stated materials.

In other words, the plurality of transistors T1, T2, T3, T4, T5, and T6 may each include oxide-based semiconductor layer and silicon-based semiconductor layer, and the gate electrodes of the plurality of transistors may be provided on the same layer although the semiconductor layers are provided on different layers. Accordingly, the display apparatus according to an embodiment of the present disclosure may be manufactured with reduced costs by reducing the number of masks that are necessary in the manufacturing processes and simplifying the processing steps. In detail, as compared with a structure where the gate electrodes are formed on different layers while an oxide-based transistor and a silicon-based transistor are used together, one sheet of mask necessary for an additional gate layer may be reduced, and the processing step of forming the additional gate electrode may be excluded, thereby obtaining a large effect on cost reduction. Moreover, because the processing step of forming the additional gate electrode is removed, defects that may occur in the corresponding process may be prevented, and thus, an effect of reducing a defective ratio in the processes of forming the display apparatus may be simultaneously obtained.

In addition, the first transistor T1 may include a semiconductor layer A01 and a gate electrode G1 that is located on the semiconductor layer A01 with the first gate insulating layer 113 therebetween. For example, the first gate insulating layer 113 may be only interposed between the first semiconductor layer A01 and the first gate electrode G1. The first conductive pattern 161 is connected to the gate electrode G1, and the first emission control line EML and the second emission control line EMBL may be provided on the same layer as the gate electrode G1.

As shown in FIG. 4, when one insulating layer is arranged between the first semiconductor layer A01 and the first gate electrode G1 in the oxide-based transistor such as the first transistor T1, the excellent electrical characteristics of the first transistor T1 that is the driving transistor may be implemented.

The second gate insulating layer 114 may be on the gate electrodes. The second gate insulating layer 114 may include an inorganic material including an oxide material or a nitride material. For example, the second gate insulating layer 114 may include at least one of silicon oxide (SiO₂), silicon nitride (SiNx), silicon oxynitride (SiON), aluminum oxide (Al₂O₃), titanium oxide (TiO₂), tantalum oxide (Ta₂O₅), hafnium oxide (HfO₂), zinc oxide (ZnO₂), etc.

As shown in FIG. 4, the second storage electrode CEs2 and the first hold electrode CEh1 may be arranged on the second gate insulating layer 114. Here, the second storage electrode CEs2 may be arranged to overlap the first storage electrode CEs1, and form the storage capacitor Cst. Likewise, the first hold electrode CEh1 may be arranged so as to overlap the second hold electrode CEh2, and form the hold capacitor Chd. That is, the second gate insulating layer 114 may act as a dielectric layer of the storage capacitor Cst and the hold capacitor Chd.

The second storage electrode CEs2 and the first hold electrode CEh1 may be located on the same layer and may include the same material. For example, the second storage electrode CEs2 and the first hold electrode CEh1 may each have a single or multi-layered structure including one or more materials selected from Al, Pt, Pd, Ag, Mg, Au, Ni, Nd, Ir, Cr, Li, Ca, Mo, Ti, W, Cu, etc.

The first interlayer insulating layer 115 may be arranged on the second storage electrode CEs2 and the first hold electrode CEh1. The first interlayer insulating layer 115 may include an inorganic material including an oxide material or a nitride material. For example, the first interlayer insulating layer 115 may include at least one selected from an insulating material such as silicon oxide (SiO₂), silicon nitride (SiNx), silicon oxynitride (SiON), aluminum oxide (Al₂O₃), titanium oxide (TiO₂), tantalum oxide (Ta₂O₅), hafnium oxide (HfO₂), and zinc oxide (ZnO₂).

A first conductive pattern 161, a second conductive pattern 162, a third conductive pattern 163, a fourth conductive pattern 164, and a first driving voltage line PL1 may be arranged on the first interlayer insulating layer 115. The first conductive pattern 161 is a node connection line of which one end may be connected to the first storage electrode CEs1 via the contact hole and the other end may be connected to the second semiconductor layer A02. The second conductive pattern 162 may be connected to the second semiconductor layer A02 via the contact hole and transfer the data signal transferred from the data line DL. The third conductive pattern 163 may be connected to the second hold electrode CEh2 via the contact hole.

The first conductive pattern 161, the second conductive pattern 162, the third conductive pattern 163, the fourth conductive pattern 164, and the first driving voltage line PL1 may include a highly conductive material such as metal, conductive oxide, etc. For example, the first conductive pattern 161, the second conductive pattern 162, the third conductive pattern 163, the fourth conductive pattern 164, and the first driving voltage line PL1 may each have a single-layered or multi-layered structure including at least one of Al, Cu, Ti, etc. In some embodiments, the first conductive pattern 161 may include a triple-layered structure including Ti/Al/Ti that are sequentially arranged.

The first planarization layer 116 may be arranged on the first conductive pattern 161, and a third conductive layer may be arranged on the first planarization layer 116. The third conductive layer may include the data line DL and the second driving voltage line PL2.

The second planarization layer 117 may be arranged on the data line DL and the second driving voltage line PL2. The first planarization layer 116 and the second planarization layer 117 may include either one or both of an organic material and an inorganic material. The organic material may include acryl, benzocyclobutene (BCB), polyimide, hexamethyldisiloxane (HMDSO), etc. The first planarization layer 116 and the second planarization layer 117 may act as protective layers covering the plurality of transistors and the plurality of peripheral transistors, and the upper portions of the first planarization layer 116 and the second planarization layer 117 may be provided to be planarized. The first and second planarization layers 116 and 117 may each have a single-layered or multi-layered structure.

The pixel defining layer 118 may be located on the second planarization layer 117. The pixel defining layer 118 increases a distance between an edge of the pixel electrode 310 and an opposite electrode 330 on the pixel electrode 310 to prevent generation of arc at the edge of the pixel electrode 310. Also, the pixel defining layer 118 may cover the edge of the pixel electrode 310 and define the light-emission region. The pixel defining layer 118 may include an organic material, for example, polyimide, HMDSO, etc.

Each of the plurality of sub-pixels may include a light-emitting device electrically connected to the circuit unit.

The light-emitting device may include the pixel electrode 310, the intermediate layer 320 including an emission layer, and an opposite electrode 330.

The pixel electrode 310 is located in the display area, and in detail, may be located on the planarization layer 117. The pixel electrode 310 is electrically connected to the thin film transistor by coming into contact with one of a source electrode and a drain electrode via a contact hole formed in the planarization layer 117, etc.

The pixel electrode 310 may include a transmissive electrode, a semi-transmissive electrode, or a reflective electrode. The pixel electrode 310 may be conductive. For example, the pixel electrode 310 may include various materials, provided that the material is conductive, e.g., a transparent conductive oxide (TCO), a conductive polymer material, etc. The pixel electrode 310 may have a single-layered or multi-layered structure. In an embodiment, the pixel electrode 310 may have a triple-layered structure respectively including indium tin oxide (ITO), Ag, and ITO.

The intermediate layer 320 and the opposite electrode 330 may be located in the opening of the pixel defining layer 118.

The intermediate layer 320 may be located on the pixel electrode 310. The intermediate layer 320 may be at least partially located in the emission region. The intermediate layer 320 may further include a hole injection layer (HIL) and a hole transport layer (HTL) arranged between the pixel electrode 310 and the emission layer, and may include an electronic transport layer (ETL) and an electron injection layer (EIL) arranged on the emission layer.

The intermediate layer 320 may include a low-molecular weight organic material or a polymer material. When the intermediate layer 320 includes a low-molecular weight material, the intermediate layer 320 may include an HIL, an HTL, an emission layer, an ETL, and EIL in a single or multiple-layered structure, and may include various organic materials such as copper phthalocyanine (CuPc), N,N’-Di(naphthalene-1-yl)-N,N’-diphenyl-benzidine (NPB), and tris-8-hydroxyquinoline aluminum (Alq₃), etc. The above layers may be manufactured by a vacuum deposition method.

When the intermediate layer 320 include a polymer material, the intermediate layer 320 may include an HTL and the emission layer. Here, the HTL may include PEDOT, and the EML may include a poly-phenylenevinylene (PPV)-based or polyfluorene-based polymer material. However, the intermediate layer 320 is not limited thereto, but may have various structures.

The opposite electrode 330 may be integrally provided over the plurality of organic light-emitting diodes to correspond to a plurality of pixel electrodes 310.

The opposite electrode 330 may be a cathode that is an electron injection electrode and may be located on the intermediate layer 320. The opposite electrode 330 may be conductive. For example, the opposite electrode 330 may include various materials, provided that the material is conductive, e.g., a TCO, a conductive polymer material, etc. The opposite electrode 330 may include Li, Ag, Mg, Al, Al-Li, Ca, Mg-In, Mg-Ag, ytterbium (Yb), Ag-Yb, ITO, IZO, or any combination thereof. The opposite electrode 330 may have a single-layered structure including a single layer or a multi-layered structure including a plurality of layers.

Because the organic light-emitting diode OLED may be easily damaged by external oxygen or moisture, a thin film encapsulation layer or a sealing substrate may be on the organic light-emitting diode OLED to cover and protect the organic light-emitting diode OLED. The thin film encapsulation layer covers the display area DA (see FIG. 2) and may extend to the outside of the display area DA (see FIG. 2). The thin film encapsulation layer may include an inorganic encapsulation layer including at least one inorganic material and an organic encapsulation layer including at least one organic material. In some embodiments, the thin film encapsulation layer may have a structure, in which a first inorganic encapsulation layer, an organic encapsulation layer, and a second inorganic encapsulation layer are stacked. The sealing substrate may be arranged facing the substrate 100, and may be bonded to the substrate 100 at the peripheral area PA (see FIG. 2) by a sealing member such as a sealant or a frit.

Also, a spacer may be further provided on the pixel defining layer 118 for preventing a dent in the mask, and various functional layers such as a polarization layer for reducing external light reflection, black matrix, a color filter, and/or a touch screen layer including a touch electrode may be provided on the thin film encapsulation layer.

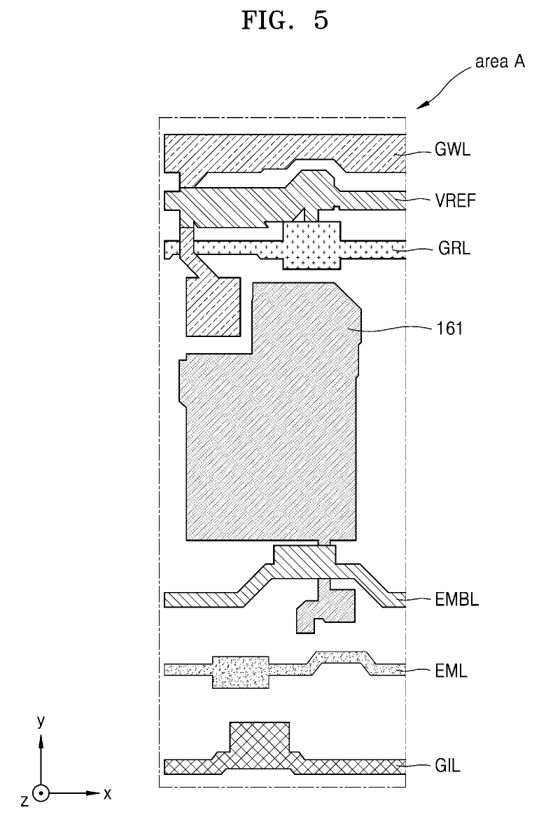

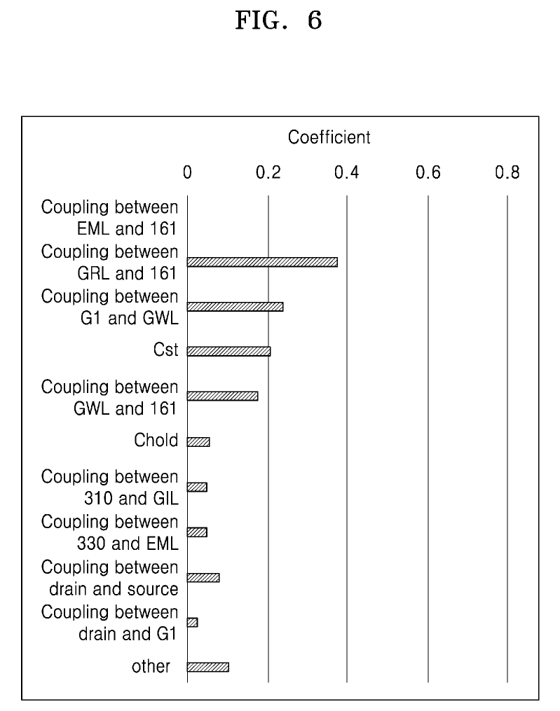

FIG. 5 is a plan view schematically showing an example of area A in FIG. 2. FIG. 6 is a graph showing a luminance scattering correlation of a display apparatus according to an embodiment of the present disclosure.

Referring to FIGS. 5 and 6, the circuit unit may include a first conductive pattern electrically connected to the light-emitting device. The first conductive pattern 161 may include molybdenum (Mo), Al, Cu, Ti, etc., and may include a single-layered structure or a multi-layered structure. The first conductive pattern 161, the second conductive pattern 162, the third conductive pattern 163, the first driving voltage line PL1, and the fourth conductive pattern 164 are disposed on the same layer and may be spaced apart from one another.

The circuit unit may include the first emission control line EML and the second emission control line EMBL extending from one side of the first conductive pattern 161 in the first direction in parallel with each other, and a gap between the first emission control line EML and the first conductive pattern 161 on a plane may be greater than a gap between the second emission control line EMBL and the first conductive pattern 161. For example, the first conductive pattern 161 may be a source electrode of the first transistor T1.

During the emission period, the fifth transistor T5 may be turned on by the emission control signal EM provided via the first emission control line EML, and the sixth transistor T6 may be turned on by the emission control signal EMB provided via the second emission control line EMBL. A driving current Id occurs according to a voltage difference between a voltage at the gate electrode G1 of the first transistor T1 and the driving voltage ELVDD, and the driving current Id is supplied to the organic light-emitting diode OLED via the sixth transistor T6. Due to characteristics of nMOS transistors, the first conductive pattern 161 is sensitive to variation in luminance and its coupling with the first emission control line EML largely affects the performance of the first conductive pattern 161. Thus, when the first emission control line EML is arranged farther away from the first conductive pattern 161 in the second direction (e.g., y-axis direction), as shown in FIG. 6, the luminance scattering may be reduced by removing the coupling between the first conductive pattern 161 and the first emission control line EML.

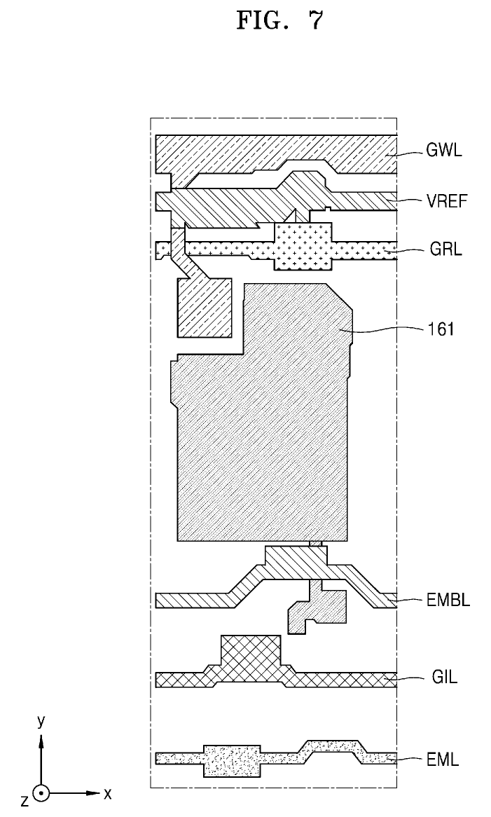

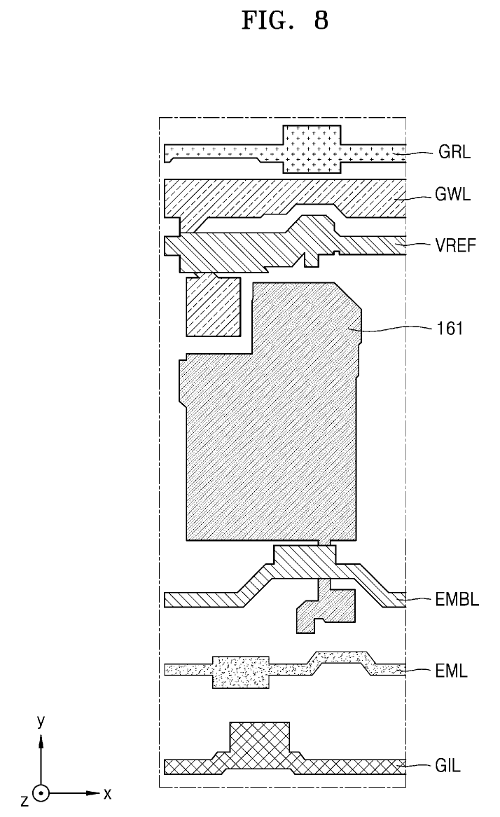

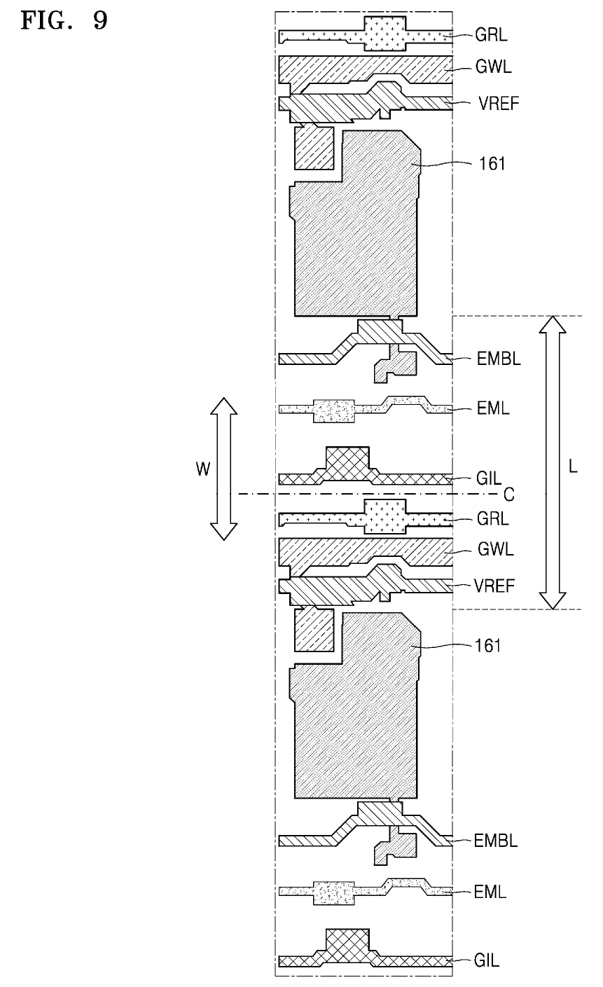

FIG. 7 is a plan view schematically showing another example of A in FIG. 2. FIG. 8 is a plan view schematically showing another example of A in FIG. 2. FIG. 9 is a plan view schematically showing another example of A in FIG. 2.

Referring to FIG. 7, the circuit unit may further include the initialization gate line GIL extending on one side of the first conductive pattern 161 in the first direction in parallel, and the initialization gate line GIL may be located between the first emission control line EBL and the first conductive pattern 161. In this case, the first emission control line EML may be arranged farther away from the first conductive pattern 161 in the second direction (e.g., y-axis direction), and the luminance scattering may be further reduced by removing or minimizing the coupling between the first conductive pattern 161 and the first emission control line EML.

Referring to FIG. 8, the circuit unit may further include the reference gate line GRL and the scan line GWL extending in parallel in the first direction on the other side of the first conductive pattern 161. The reference gate line GRL and the scan line GWL may be located at the same layer as that of the gate electrode G1.

A gap between the reference gate line GRL and the first conductive pattern 161 on a plane may be greater than a gap between the scan line GWL and the first conductive pattern 161. While the coupling between the first conductive pattern 161 and the first emission control line EML is removed, as shown in FIG. 6, the luminance scattering may be largely affected by the coupling between the reference gate line GRL and the first conductive pattern 161. Therefore, as shown in FIG. 8, when the gap between the reference gate line GRL and the first conductive pattern 161 is greater than the gap between the scan line GWL and the first conductive pattern 161 on a plane, the reference gate line GRL is arranged away from the first conductive pattern 161 in the second direction (e.g., y-axis direction) to lessen the coupling between the first conductive pattern 161 and the reference gate line GRL, and thus, the luminance scattering may be further reduced.

In particular, the initialization gate line GIL is located between the first emission control line EBL and the first conductive pattern 161 as shown in FIG. 7, and thus, on one side of the first conductive pattern 161, when the first emission control line EML extending in parallel in the first direction is arranged farthest from the first conductive pattern 161, and on the other side of the first conductive pattern 161, when the reference gate line GRL extending in parallel in the first direction is arranged farthest from the first conductive pattern 161, the luminance scattering may be further reduced.

Each of the plurality of sub-pixels may include the light-emitting device and the pixel circuit PC outputting a driving current to the light-emitting device. For example, as shown in FIG. 9, the plurality of sub-pixels may include a first sub-pixel SP1 and a second sub-pixel SP2 that are arranged parallel to each other in the second direction that is perpendicular to the first direction. The first sub-pixel SP1 and the second sub-pixel SP2 may each emit red light, green light, or blue light.

Referring to FIG. 9, the first emission control line EML of the first sub-pixel SP1 and the reference gate line GRL of the second sub-pixel SP2 may be arranged adjacent to each other. The statement that the first emission control line EML of the first sub-pixel SP1 and the reference gate line GRL of the second sub-pixel SP2 are arranged adjacent to each other denotes that the first emission control line EML of the first sub-pixel SP1 and the reference gate line GRL of the second sub-pixel SP2 are arranged away from the first conductive pattern 161 in the second direction (e.g., y-axis direction).

A width w of a region where the first emission control line EML of the first sub-pixel SP1 and the reference gate line GRL of the second sub-pixel SP2 are arranged in the second direction may be 30% or less of a gap L between the first conductive pattern 161 of the first sub-pixel SP1 and the first conductive pattern 161 of the second sub-pixel SP2. This may be achieved when the first emission control line EML is arranged away from the first conductive pattern 161 in the second direction (e.g., y-axis direction), and at the same time, when the reference gate line GRL is also arranged away from the first conductive pattern 161 in the second direction (e.g., y-axis direction). Accordingly, the coupling between the first conductive pattern 161 and the first emission control line EML, and the reference gate line GRL may be removed and lessened, thereby further reducing the luminance scattering.

Referring to FIG. 9, the region where the first emission control line EML of the first sub-pixel SP1 and the reference gate line GRL of the second sub-pixel SP2 are arranged in the second direction may be located at a center portion C between the first conductive pattern 161 of the first sub-pixel SP1 and the first conductive pattern 161 of the second sub-pixel SP2.

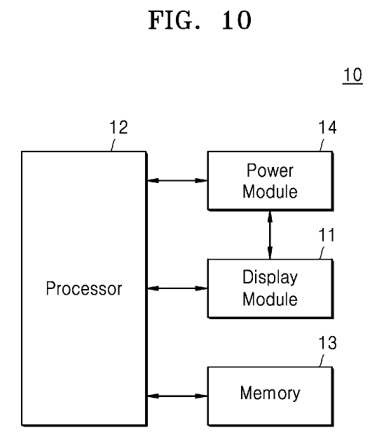

FIG. 10 is a cross-sectional view of an electronic device according to an embodiment of the present disclosure.

Referring to FIG. 10, an electronic device 10 according to an embodiment may include a display module 11, a processor 12, a memory 13, and a power module 14.

The display module 11 may include organic light emitting diodes, quantum-dot organic light emitting diodes, micro-light-emitting diodes, nano-light-emitting diodes, liquid crystals, not being limited thereto.

The processor 12 may include at least one of a central processing unit (CPU), an application processor (AP), a graphic processing unit (GPU), a communication processor (CP), an image signal processor (ISP), and a controller.

The memory 13 may store data information that is necessary in operations of the processor 12 or the display module 11. When the processor 12 executes an application stored in the memory 13, an image data signal and/or an input control signal is transferred to the display module 11, and the display module 11 may process the transferred signal and output image information through a display screen.

The power module 14 may include a power supply module such as a power adaptor or a battery device, and a power converter that converts the power supplied by the power supply module and generates electric power that is necessary for the operations of the electronic device 10.

At least one of components in the electronic device 10 may be included in the display apparatus according to the above embodiment. Also, some of individual modules functionally included in one module may be included in the display apparatus and some other modules may be provided separately from the display apparatus. For example, the display apparatus may include the display module 11, and the processor 12, the memory 13, and the power module 14 may be provided in the form of other devices, not the display apparatus, in the electronic device 10.

At least one of the components, elements, modules or units (collectively "components" in this paragraph) represented by a block or an equivalent indication in the drawings including FIG. 10 may be implemented or embodied by analog and/or digital circuits including one or more of a logic gate, an integrated circuit, a microprocessor, a microcontroller, a memory circuit, a passive electronic component, an active electronic component, an optical component, and the like. Alternatively or additionally, these components may be implemented or embodied by software including one or more instructions stored in an internal or external storage medium that is readable by at least one processor. For example, the at least one processor may invoke at least one of the one or more instructions stored in the storage medium, and execute it, with or without using one or more other components under the control of the at least one processor. This allows the at least one processor to perform at least one function or operation described above as being performed by each of the components according to the at least one instruction invoked. Here, the at least one processor may include a central processing unit, a graphic processing unit, another type of microprocessor, not being limited thereto.

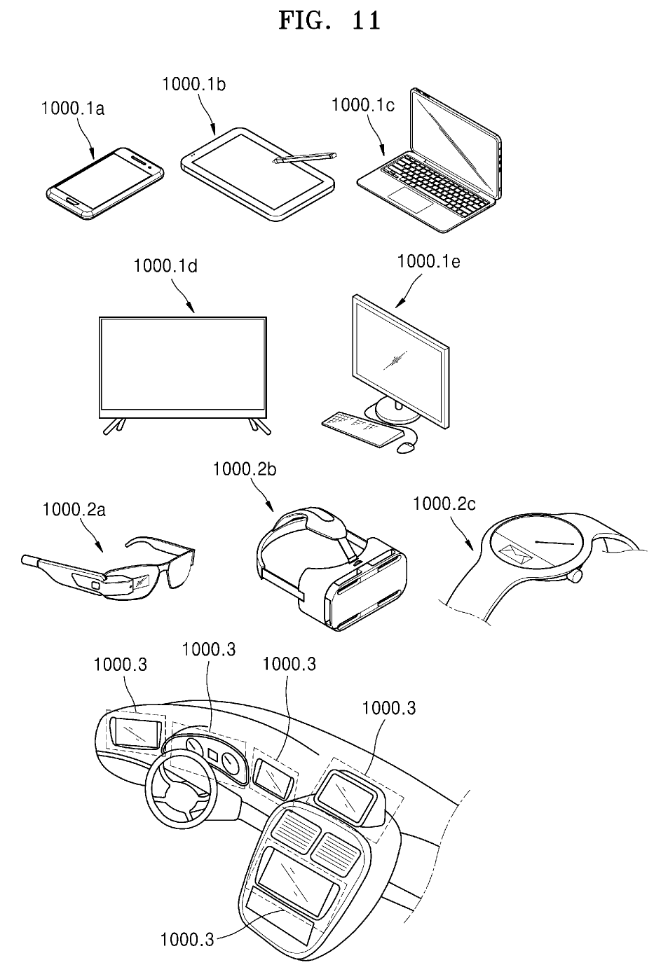

FIG. 11 is schematic diagrams showing electronic devices including the display panel of FIG. 1 according to some embodiments.

Referring to FIG. 11, various electronic devices to which the display apparatus according to the embodiment is applied may not only include electronic devices for displaying images such as a smartphone 1000.1a, a tablet PC 1000.1b, a laptop computer 1000.1c, a TV 1000.1d, a desk monitor 1000.1e, etc., but may also include wearable electronic devices including a display module such as smart glasses 1000.2a, a head-mounted display 1000.2b, a smart watch 1000.2c, etc., and electronic devices 1000.3 for vehicle including a display module such as a dashboard of a vehicle, a center fascia, a center information display (CID) arranged on a dashboard, a room mirror display, etc.

In one or more embodiments of the present disclosure, a display apparatus may include a plurality of sub-pixels. Each of the plurality of sub-pixels may include: a light-emitting device; and an electronic circuit including a first conductive pattern connected to the light-emitting device, and a first emission control line and a second emission control line that extend in a first direction on one side of the first conductive pattern. A gap between the first emission control line and the first conductive pattern, in a planar view, is greater than a gap between the second emission control line and the first conductive pattern.

The electronic circuit may include an initialization gate line extending in the first direction on the one side of the first conductive pattern, and the initialization gate line is between the first emission control line and the first conductive pattern.

The electronic circuit may include a reference gate line and a scan line that extend in the first direction on an opposite side of the first conductive pattern, and a gap between the reference gate line and the first conductive pattern, in the planar view, is greater than a gap between the scan line and the first conductive pattern.

The electronic circuit may include a reference gate line and a scan line that extend in the first direction on an opposite side of the first conductive pattern, and a gap between the reference gate line and the first conductive pattern, in the planar view, is greater than a gap between the scan line and the first conductive pattern.

The plurality of sub-pixels may include a first sub-pixel and a second sub-pixel that are arranged in a second direction that is perpendicular to the first direction, and the first emission control line of the first sub-pixel and the reference gate line of the second sub-pixel are arranged adjacent to each other.

A width of a region where the first emission control line of the first sub-pixel and a reference gate line of the second sub-pixel are arranged in the second direction is less than or equal to 30% of a gap between the first conductive pattern of the first sub-pixel and the first conductive pattern of the second sub-pixel.

A region where the first emission control line of the first sub-pixel and a reference gate line of the second sub-pixel are arranged in the second direction is at a center portion between the first conductive pattern of the first sub-pixel and the first conductive pattern of the second sub-pixel.

The electronic circuit may include a thin film transistor including a semiconductor layer and a gate electrode, the gate electrode being above the semiconductor layer with a gate insulating layer therebetween, the first conductive pattern is connected to the gate electrode, and the first emission control line and the second emission control line are on a same layer as the gate electrode.

The electronic circuit may include a reference gate line and a scan line that extend in the first direction on an opposite side of the first conductive pattern, and the reference gate line and the scan line are on a same layer as the gate electrode.

The light-emitting device may include a pixel electrode connected to the thin film transistor, an opposite electrode on the pixel electrode, and an intermediate layer between the pixel electrode and the opposite electrode and including an emission layer.

In one or more embodiments of the present disclosure, a display apparatus may include: a plurality of sub-pixels arranged in a first direction and a second direction perpendicular to the first direction, wherein each of the plurality of sub-pixels may include an electronic circuit, the electronic circuit may include a thin film transistor, a light-emitting device connected to the thin film transistor, a first conductive pattern connected to the light-emitting device, and a first emission control line and a second emission control line that extend in the first direction on one side of the first conductive pattern, a reference gate line and a scan line that extend in the first direction on an opposite side of the first conductive pattern, the plurality of sub-pixels may include a first sub-pixel and a second sub-pixel that are immediately next to each other in the second direction from among the plurality of sub-pixels, and the first emission control line of the first sub-pixel and the reference gate line of the second sub-pixel are arranged adjacent to each other in an area between the first conductive pattern of the first sub-pixel and the first conductive pattern of the second sub-pixel.

A gap between the first emission control line and the first conductive pattern, in a planar view, is greater than a gap between the second emission control line and the first conductive pattern.

The electronic circuit may include an initialization gate line extending in the first direction on one side of the first conductive pattern, and the initialization gate line is between the first emission control line and the first conductive pattern.

The reference gate line and the scan line extend in the first direction on an opposite side of the first conductive pattern, and a gap between the reference gate line and the first conductive pattern, in the planar view, is greater than a gap between the scan line and the first conductive pattern.

The reference gate line and the scan line extend in the first direction on an opposite side of the first conductive pattern, and a gap between the reference gate line and the first conductive pattern, in a planar view, is greater than a gap between the scan line and the first conductive pattern.

A width of a region where the first emission control line of the first sub-pixel and the reference gate line of the second sub-pixel are arranged in the second direction is less than or equal to 30% of a gap between the first conductive pattern of the first sub-pixel and the first conductive pattern of the second sub-pixel.

A region where the first emission control line of the first sub-pixel and the reference gate line of the second sub-pixel are arranged in the second direction is at a center portion between the first conductive pattern of the first sub-pixel and the first conductive pattern of the second sub-pixel.

The thin film transistor may include a semiconductor layer and a gate electrode, the gate electrode being above the semiconductor layer with a gate insulating layer therebetween, the first conductive pattern is connected to the gate electrode, and the first emission control line and the second emission control line are on a same layer as the gate electrode.

The reference gate line and the scan line extend in the first direction on an opposite side of the first conductive pattern, and the reference gate line and the scan line are on a same layer as the gate electrode.

In one or more embodiments of the present disclosure, an electronic device may include a display apparatus including a display panel generating images, a processor, a memory, and a power supply, wherein the display apparatus may include a plurality of sub-pixels, each of the plurality of sub-pixels may include: an electronic circuit; and a light-emitting device connected to the electronic circuit, the electronic circuit may include a first conductive pattern connected to the light-emitting device, and a first emission control line and a second emission control line that extend in a first direction on one side of the first conductive pattern, and a gap between the first emission control line and the first conductive pattern, in a planar view, is greater than a gap between the second emission control line and the first conductive pattern.

The display apparatus and the electronic device including the same according to the present disclosure may improve luminance unevenness due to the reduction in the luminance scattering.

It should be understood that embodiments described herein should be considered in a descriptive sense only and not for purposes of limitation. Descriptions of features or aspects within each embodiment should typically be considered as available for other similar features or aspects in other embodiments.

While one or more embodiments have been described with reference to the figures, it will be understood by those of ordinary skill in the art that various changes in form and details may be made therein without departing from the spirit and scope as defined by the following claims.

What is claimed is:

1. A display apparatus comprising a plurality of sub-pixels,
wherein each of the plurality of sub-pixels comprises:
a light-emitting device; and
an electronic circuit comprising a first conductive pattern connected to the light-emitting device, and a first emission control line and a second emission control line that extend in a first direction on one side of the first conductive pattern, and
wherein a gap between the first emission control line and the first conductive pattern, in a planar view, is greater than a gap between the second emission control line and the first conductive pattern.

2. The display apparatus of claim 1, wherein
the electronic circuit further comprises an initialization gate line extending in the first direction on the one side of the first conductive pattern, and
the initialization gate line is between the first emission control line and the first conductive pattern.

3. The display apparatus of claim 1, wherein
the electronic circuit further comprises a reference gate line and a scan line that extend in the first direction on an opposite side of the first conductive pattern, and
a gap between the reference gate line and the first conductive pattern, in the planar view, is greater than a gap between the scan line and the first conductive pattern.

4. The display apparatus of claim 2, wherein
the electronic circuit further comprises a reference gate line and a scan line that extend in the first direction on an opposite side of the first conductive pattern, and
a gap between the reference gate line and the first conductive pattern, in the planar view, is greater than a gap between the scan line and the first conductive pattern.

5. The display apparatus of claim 1, wherein
the plurality of sub-pixels comprises a first sub-pixel and a second sub-pixel that are arranged in a second direction that is perpendicular to the first direction, and
the first emission control line of the first sub-pixel and the reference gate line of the second sub-pixel are arranged adjacent to each other.

6. The display apparatus of claim 5, wherein
a width of a region where the first emission control line of the first sub-pixel and a reference gate line of the second sub-pixel are arranged in the second direction is less than or equal to 30% of a gap between the first conductive pattern of the first sub-pixel and the first conductive pattern of the second sub-pixel.

7. The display apparatus of claim 5, wherein
a region where the first emission control line of the first sub-pixel and a reference gate line of the second sub-pixel are arranged in the second direction is at a center portion between the first conductive pattern of the first sub-pixel and the first conductive pattern of the second sub-pixel.

8. The display apparatus of claim 1, wherein
the electronic circuit comprises a thin film transistor comprising a semiconductor layer and a gate electrode, the gate electrode being above the semiconductor layer with a gate insulating layer therebetween,
the first conductive pattern is connected to the gate electrode, and
the first emission control line and the second emission control line are on a same layer as the gate electrode.

9. The display apparatus of claim 8, wherein
the electronic circuit further comprises a reference gate line and a scan line that extend in the first direction on an opposite side of the first conductive pattern, and
the reference gate line and the scan line are on a same layer as the gate electrode.

10. The display apparatus of claim 8, wherein
the light-emitting device comprises a pixel electrode connected to the thin film transistor, an opposite electrode on the pixel electrode, and an intermediate layer between the pixel electrode and the opposite electrode and comprising an emission layer.

11. A display apparatus comprising:
a plurality of sub-pixels arranged in a first direction and a second direction perpendicular to the first direction,
wherein each of the plurality of sub-pixels comprises an electronic circuit,
the electronic circuit comprises a thin film transistor, a light-emitting device connected to the thin film transistor, a first conductive pattern connected to the light-emitting device, and a first emission control line and a second emission control line that extend in the first direction on one side of the first conductive pattern,
a reference gate line and a scan line that extend in the first direction on an opposite side of the first conductive pattern,
the plurality of sub-pixels comprises a first sub-pixel and a second sub-pixel that are immediately next to each other in the second direction from among the plurality of sub-pixels, and
the first emission control line of the first sub-pixel and the reference gate line of the second sub-pixel are arranged adjacent to each other in an area between the first conductive pattern of the first sub-pixel and the first conductive pattern of the second sub-pixel.

12. The display apparatus of claim 11, wherein
a gap between the first emission control line and the first conductive pattern, in a planar view, is greater than a gap between the second emission control line and the first conductive pattern.

13. The display apparatus of claim 11, wherein
the electronic circuit further comprises an initialization gate line extending in the first direction on one side of the first conductive pattern, and
the initialization gate line is between the first emission control line and the first conductive pattern.

14. The display apparatus of claim 12, wherein
the reference gate line and the scan line extend in the first direction on an opposite side of the first conductive pattern, and
a gap between the reference gate line and the first conductive pattern, in the planar view, is greater than a gap between the scan line and the first conductive pattern.

15. The display apparatus of claim 13, wherein
the reference gate line and the scan line extend in the first direction on an opposite side of the first conductive pattern, and
a gap between the reference gate line and the first conductive pattern, in a planar view, is greater than a gap between the scan line and the first conductive pattern.

16. The display apparatus of claim 11, wherein
a width of a region where the first emission control line of the first sub-pixel and the reference gate line of the second sub-pixel are arranged in the second direction is less than or equal to 30% of a gap between the first conductive pattern of the first sub-pixel and the first conductive pattern of the second sub-pixel.

17. The display apparatus of claim 11, wherein
a region where the first emission control line of the first sub-pixel and the reference gate line of the second sub-pixel are arranged in the second direction is at a center portion between the first conductive pattern of the first sub-pixel and the first conductive pattern of the second sub-pixel.

18. The display apparatus of claim 11, wherein
the thin film transistor comprises a semiconductor layer and a gate electrode, the gate electrode being above the semiconductor layer with a gate insulating layer therebetween,
the first conductive pattern is connected to the gate electrode, and
the first emission control line and the second emission control line are on a same layer as the gate electrode.

19. The display apparatus of claim 18, wherein
the reference gate line and the scan line extend in the first direction on an opposite side of the first conductive pattern, and
the reference gate line and the scan line are on a same layer as the gate electrode.

20. An electronic device comprising a display apparatus comprising a display panel generating images, a processor, a memory, and a power supply,
wherein the display apparatus comprises a plurality of sub-pixels,
each of the plurality of sub-pixels comprises:
an electronic circuit; and
a light-emitting device connected to the electronic circuit,
the electronic circuit comprises a first conductive pattern connected to the light-emitting device, and a first emission control line and a second emission control line that extend in a first direction on one side of the first conductive pattern, and
a gap between the first emission control line and the first conductive pattern, in a planar view, is greater than a gap between the second emission control line and the first conductive pattern.
